(19) United States
(12) Patent Application Publication
(10) Pub. No.: US 2018/0301368 A1
(43) Pub. Date: Oct. 18, 2018

(54) WAFER PROCESSING DEVICE

(71) Applicant: SAMCO INC., Kyoto-shi (JP)

(72) Inventors: Tomoyuki NONAKA, Kyoto-shi (JP); Akimi UCHIDA, Kyoto-shi (JP)

(73) Assignee: SAMCO INC., Kyoto-shi (JP)

(21) Appl. No.: 15/921,996

(22) Filed: Mar. 15, 2018

(30) Foreign Application Priority Data
Apr. 14, 2017 (JP) 2017-080328

(51) Int. Cl. H01L 21/687; H01L 21/683; H01L 21/67

(52) U.S. Cl. CPC H01L 21/68742; H01L 21/6836; H01L 21/78; H01L 21/6833; H01L 21/67069; H01L 21/68721

(57) ABSTRACT

A wafer processing device is a device for handling a framed wafer including a frame, a film stretched inside the frame, and a wafer attached on the film, to perform a plasma processing on the wafer. The device includes: a wafer stage on which the wafer is to be placed via the film; a plurality of vertically movable frame-lifting pins arranged around the wafer stage, for supporting the frame; and a frame-lifting-pin drive controller for lowering the individual frame-lifting pins with different timings. With this device, the film with the attached wafer can be neatly placed on the wafer stage (i.e. with no wrinkle in the film as well as no bubble between the film and the wafer stage).

### TECHNICAL FIELD

The present invention relates to a wafer processing device for performing various plasma processings on a semiconductor wafer.

### BACKGROUND ART

As one of the various kinds of plasma processings performed on a semiconductor wafer, an etching process for cutting a wafer (the so-called “plasma dicing”) is commonly known. Specifically, in the plasma dicing processing, a single wafer on which a number of unit circuits have been created is divided and cut into the individual unit circuits by etching linear zones between the unit circuits with plasma (those zones are also called “streets”).

As shown in FIG. 1, before the plasma dicing processing, the wafer 90 to be processed is attached on a film 91 having an adhesive surface on one side. The circumference of this film 91 is adhered to a frame 92 (which normally has an annular shape). In other words, the wafer 90 is attached on to and supported by the film 91 stretched over the frame 92 (this may be hereinafter called the “framed wafer 9”). By being attached on the film 91, the individual unit circuits obtained by the dividing and cutting process are prevented from being scattered. Furthermore, supporting the film 91 by the frame 92 facilitates the handling of the wafer 90.

One mode of the plasma dicing processing of a framed wafer 9 using a common type of plasma processing device 800 as shown in FIG. 11 is hereinafter described.

A framed wafer 9 is stored on each shelf of a cassette C as shown in FIG. 2. Each wafer is individually removed from the cassette C by the hand of an external transfer system (not shown) and transferred to a position above the stage 802 placed within the housing 801 of the plasma processing chamber 800.

On the stage 802, a plurality of frame-lifting pins 803 for supporting the frame 92 of the framed wafer 9 are provided. The external transfer system holding the framed wafer 9 with its hand transfers this wafer onto those frame-lifting pins 803 (as indicated by the solid lines in FIG. 11).

A pin drive mechanism 804 for synchronously changing the vertical position of the group of frame-lifting pins 803 is connected to those pins. After the framed wafer 9 has been placed on the frame-lifting pins 803, the pin drive mechanism 804 simultaneously lowers the group of frame-lifting pins 803. As a result, the framed wafer 9 on the supporting pins 803 is set on the stage 802 (as indicated by the long dashed short dashed line in FIG. 11).

After the framed wafer 9 has been set on the stage 802, a predetermined kind of gas is introduced into the housing 802. Additionally, a radio-frequency power for plasma formation is supplied to the radio-frequency coil (not shown) located immediately above the housing 801. A biasing radio-frequency power is also supplied to an electrode (not shown) embedded in the stage 802. As a result, a cloud of plasma is formed above the wafer 90, causing the surface of this wafer 90 to be progressively etched with the thereby generated reactive ions in the plasma. It should be noted that a mask which covers the areas other than the streets is previously formed on the surface of the wafer 90. Accordingly, only the street portions which are not covered with the mask undergo the etching. Consequently, the wafer 90 is divided and cut into individual unit circuits. The divided and cut wafer 90 is retained on the film 91 in a neatly arrayed form.

### CITATION LIST

### Patent Literature

Patent Literature 1: JP 2016-510168 A

### SUMMARY OF INVENTION

### Technical Problem

In recent years, with the downsizing and sophistication of electronic devices, the downsizing of electronic circuits used in those devices has also been increasingly required. For the downsizing of electronic circuits, it is essential to reduce the thickness of the wafer used as their substrates. In recent years, wafers have been as thin as several ten micrometers. Since commonly used silicon wafers have a diameter of 200-300 mm, it is difficult to directly handle a wafer having such a thickness. Accordingly, the wafer is attached on and supported by a film stretched over a frame, as described earlier.

The film used for this task also has a small thickness of several ten micrometers in order to ensure a sufficient degree of adhesion between the wafer and the supporting film. Accordingly, in most cases, the thickness of the two elements as combined together (a film with a wafer attached is hereinafter called the “wafer-attached sheet”) does not exceed 100 micrometers. When a wafer-attached sheet having such a thickness is held on a frame whose inner diameter is larger than 200-300 mm, there must be an allowance for a certain amount of sag in the wafer-attached sheet.

If there is a sag in the wafer-attached sheet, an undesirable situation may occur, such as the wrinkling of the wafer-attached sheet or formation of bubbles between the wafer-attached sheet and the stage, when the wafer-attached sheet is placed onto the stage in the previously described manner by lowering the frame-lifting pins while supporting the frame which holds the outer circumference of the film. In other words, the wafer-attached sheet may not be neatly placed on the stage.

Patent Literature 1 proposes the idea of applying a tensional force to the film and clamping the wafer to the stage to prevent the formation of wrinkles or bubbles.

However, the mechanism for applying a tensional force to the film makes the device more complex in structure and increases its cost. Additionally, if the film is extremely thin, the application of the tensional force to the film may possibly cause damage to the film. Besides, if a wrinkle or bubble is already present when the wafer-attached sheet has been placed on the stage, it is difficult to completely remove this defect by clamping the wafer to the stage.

The problem to be solved by the present invention is to provide a technique which guarantees that the wafer-attached sheet will be neatly placed on the stage (i.e. with no wrinkle in the wafer-attached sheet as well as no bubble between the wafer-attached sheet and the stage).

### Solution to Problem

A wafer processing device according to the present invention developed for solving the previously described problem is a device used for plasma-processing a wafer with a workpiece unit including a frame, a film stretched inside the frame, and the wafer attached on the film, the wafer processing device including:

a) a stage on which the wafer is to be placed via the film;

b) a plurality of vertically movable frame-lifting pins arranged around the stage, for supporting the frame; and

c) a frame-lifting-pin drive controller for lowering the plurality of frame-lifting pins individually with different timings.

In the wafer processing device according to the present invention, a wafer may be placed onto the stage as follows: Initially, the frame of the workpiece unit is supported by the plurality of frame-lifting pins. Next, the frame-lifting-pin drive controller lowers the frame-lifting pins individually with different timings in such a manner as to make only a portion of the lower surface of the film with the wafer attached initially come in contact with the stage, rather than making the entire surface of the film simultaneously come in contact with the stage. Subsequently, the controller controls the timing of lowering each of the plurality of frame-lifting pins so that the contact area gradually extends from the initial contact portion to other portions, until the entire lower surface of the film comes in contact with the stage. By such an operation, both the film and the wafer attached on the film can be neatly placed on the stage.

Preferably, the wafer processing device may further include:

d) a pressing element for pressing the film outside the wafer onto the stage.

According to this configuration, after the film with the wafer attached has been neatly placed on the stage in the previously described manner, the film outside the wafer is pressed onto the stage with the pressing element, whereby a securer fixation of the wafer to the stage is achieved during the plasma processing of the wafer, so that the plasma processing can be more accurately performed. Furthermore, if the stage is provided with a mechanism for cooling the wafer (e.g. a space, groove or the like for passing a coolant, such as helium gas), the cooling can be more assuredly performed.

Even in the case where the device is provided with the pressing element, the stage itself may additionally include a mechanism for fixing the wafer to the stage, such as an electrostatic chuck mechanism.

Preferably, the pressing element may be configured to press the film located just outside the wafer along the entire circumference of the wafer.

According to this configuration, when a coolant is passed through the stage, the coolant is prevented from leaking through a gap between the film and the stage. Accordingly, the wafer can be more efficiently cooled.

Preferably, the pressing element may be configured to cover, in a contactless form, the frame as well as the film outside the film pressed by the pressing element.

This configuration can prevent the situation where the film is damaged due to exposure to the plasma. The generation of particles from the frame and the film due to their exposure to the plasma can also be prevented.

Preferably, the stage may include:

a frame-shaped bank part for supporting the film just outside the wafer;

a base part surrounded by the bank part; and

a plurality of projections provided on the base part, each of the plurality of projections having an upper end at the same height as the upper surface of the bank part.

For example, if the wafer has a circular shape, the frame-shaped bank part should be shaped like a ring. If the wafer has a rectangular shape, the bank part should be shaped like a rectangle similar to the wafer.

According to this configuration, when the wafer is set on the stage, the wafer is supported by the plurality of projections formed on the base part surrounded by the bank part, thereby allowing a coolant to be passed into the space surrounded by the wafer and the bank part so as to cool the wafer.

Preferably, the stage may include an electrostatic chuck mechanism which includes:

a dielectric layer serving as the base part; and

an electrode located within an inner area than the bank part as viewed from above and at a lower level than the upper surface of the dielectric layer.

According to this configuration, the wafer can be fixed to the stage by the electrostatic chuck mechanism. Since the electrode is embedded within an inner area than the bank part as viewed from above, no electrostatic adsorption force acts on the bank part. This configuration prevents the film just outside the wafer from being adsorbed, so that the film can be easily separated from the stage.

Preferably, the device may include a frame stage circumferentially surrounding the aforementioned stage, leaving a space from the aforementioned stage; and

the plurality of frame-lifting pins are provided in the frame stage.

According to this configuration, the presence of the space between the frame stage and the stage facilitates maintenance work.

A wafer processing device according to another aspect of the present invention is a device used for plasma-processing a wafer with a workpiece unit including a frame, a film stretched inside the frame, and the wafer attached on the film, the wafer processing device including:

a) a stage on which the wafer is to be placed via the film, the stage having a top surface including a curved surface bulging upward; and

b) a plurality of vertically movable frame-lifting pins arranged around the stage, for supporting the frame.

In this wafer processing device, a wafer can be placed onto the stage as follows: Initially, the frame of the workpiece unit is supported by the plurality of frame-lifting pins. Next, those frame-lifting pins are lowered, for example, at the same time. Since the stage has a top surface including a curved surface bulging upward, only a portion (typically, central portion) of the lower surface of the film with the attached wafer initially comes in contact with the stage, rather than the entire surface of the film simultaneously coming in contact with the stage. Subsequently, the contact area gradually extends from the initial contact portion to other portions, until the entire lower surface of the film comes in contact with the stage. As a result, both the film and the wafer attached on the film are neatly placed on the stage.

### Advantageous Effects of the Invention

In the wafer processing device according to the present invention, a film with a wafer attached is placed onto the stage in such a manner that only a portion of the lower surface of the film initially comes in contact with the stage, and subsequently, the contact area gradually extends from the initial contact portion to other portions, until the entire lower surface of the film comes in contact with the stage, rather than the entire surface of the film simultaneously coming in contact with the stage. By such an operation, both the film and the wafer attached on the film are neatly placed on the stage.

### BRIEF DESCRIPTION OF DRAWINGS

FIG. 1 is a perspective view and sectional side view of a framed wafer to be processed by a wafer processing device.

FIG. 2 is a perspective view of a cassette for storing framed wafers.

FIG. 3 is a sectional side view schematically showing the configuration of a wafer processing device.

FIG. 4 is a top view of a wafer stage and a frame stage, as well as top views of a framed wafer and a pressing device.

FIGS. 5A-5D are diagrams schematically showing the state of components of the wafer processing device at each stage of a sequence of operations performed by the same device.

FIG. 6 is a sectional side view schematically showing the configuration of a wafer processing device according to the first variation.

FIG. 7 is a sectional side view and a top view showing the configuration of the main components of a wafer processing device according to the second variation.

FIGS. 8A-8C are sectional side views showing the configuration of the main components of a wafer processing device according to the third variation.

FIG. 9 is a sectional side view showing the configuration of the main components of a wafer processing device according to the fourth variation.

FIG. 10 is a sectional side view showing the configuration of the main components of a wafer processing device according to the fifth variation.

FIG. 11 is a sectional side view schematically showing the configuration of a conventional wafer processing device.

### DESCRIPTION OF EMBODIMENTS

An embodiment of the present invention is hereinafter described with reference to the attached drawings. The following embodiment is a mere example which embodies the present invention, and therefore, should not be construed as limiting the technical scope of the present invention. For convenience of explanation, the drawings show only the components which are relevant to the present invention. Some components are omitted from the drawings.

### 1. Overall Configuration of Wafer Processing Device

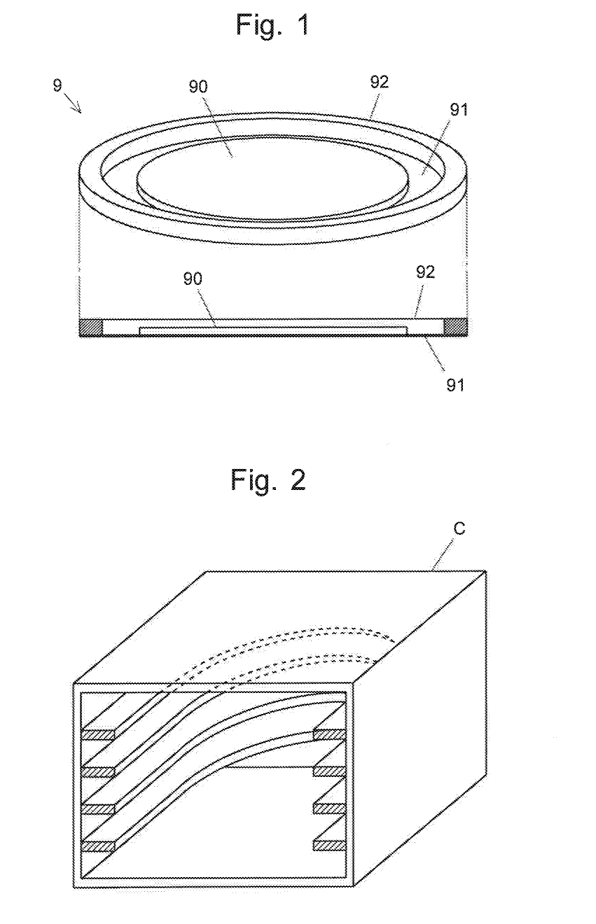

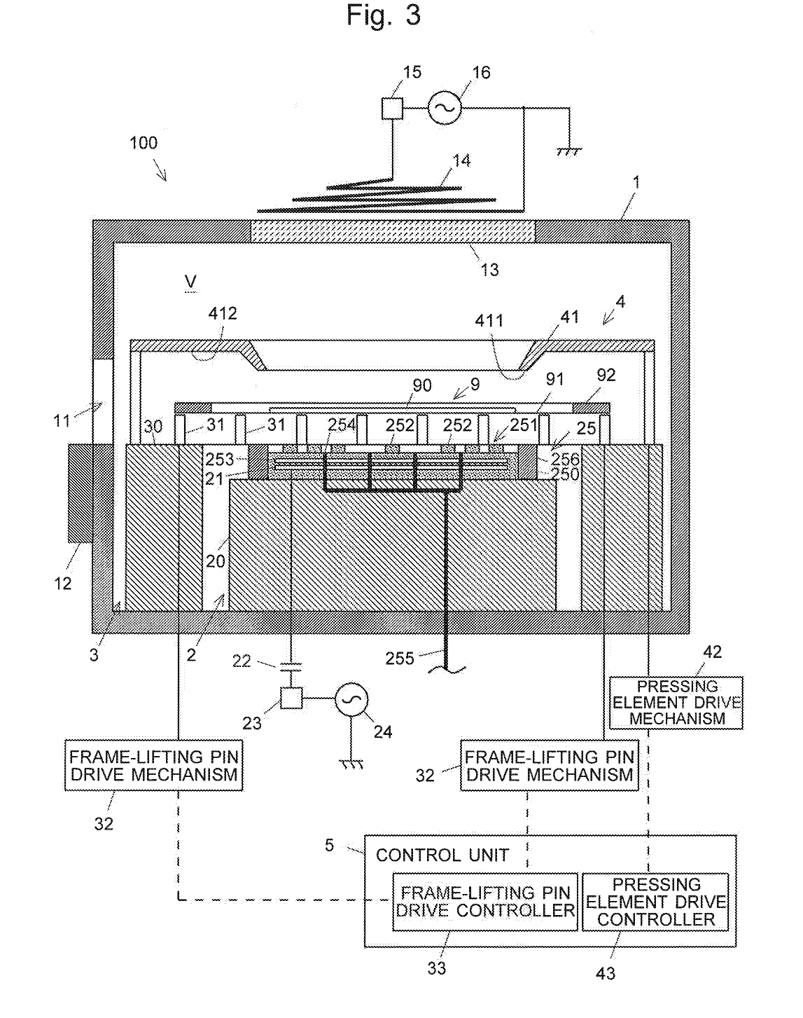

The configuration of a wafer processing device according to the present embodiment is described with reference to FIGS. 1-3. FIG. 1 is a perspective view and sectional side view of a framed wafer 9 to be processed by the wafer processing device (this wafer corresponds to the “workpiece unit” in the present invention). FIG. 2 is a perspective view of a cassette C for storing the framed wafer 9. FIG. 3 is a sectional side view schematically showing the configuration of the wafer processing device 100.

The wafer processing device 100 is a device for performing a plasma processing on a wafer (semiconductor wafer) 90. More specifically, the device is used for performing a plasma dicing processing for dividing and cutting the wafer 90 into individual unit circuits. As shown in FIG. 1, the wafer 90 to be processed by this wafer processing device 100 is attached on and supported by a film 91 stretched inside an annular frame 92 (framed wafer 9).

The wafer processing device 100 includes a housing 1 forming a processing space V inside. The housing 1 has a transfer opening 11 for the transfer of the framed wafer 9 between the processing space V and the outside, as well as a load lock 12 for closing the opening. A dielectric window 13 is provided in the top plate of the housing 1. A radio-frequency coil 14 is placed directly above the processing space V, with the dielectric window 13 in between. A radio-frequency power source (radio-frequency power source for plasma) 16 is connected to the radio-frequency coil 14 via a matching circuit 15, thereby allowing for the supply of radio-frequency power to the radio-frequency coil 14. For example, a 13.56 MHz radio-frequency power source can be used as the radio-frequency power source for plasma 16.

Additionally, the housing 1 is provided with a gas introduction port for introducing various kinds of gas into the processing space V, and a gas supply source is connected to the gas introduction port via a pipe in which a valve and other related components are provided (the gas introduction port and related components are not shown). The housing 1 is also provided with an evacuation port for evacuating the processing space V, and a vacuum pump is connected to the evacuation port via a pipe in which a valve and other related components are provided (the evacuation port and related components are not shown).

In the processing space V, a stage (wafer stage) 2 having a circular shape in a planar view is provided. On the outside of the wafer stage 2, a frame stage 3 having a ring-like shape in a planar view and surrounding the wafer stage 2 is provided. A pressing device 4 is located above those stages. The wafer stage 2 and the frame stage 3 may be placed leaving a space in between (i.e. a gap may be present between the outer sidewall of the wafer stage 2 and the inner sidewall of the frame stage 3), or they may be integrally formed. The former configuration facilitates the maintenance work of each component. The latter configuration allows for the downsizing of the device structure. Configurations of the wafer stage 2, frame stage 3 and pressing device 4 will be described later in detail.

The wafer processing device 100 further includes a control unit 5 for controlling each section of the device. The control unit 5 includes a personal computer as its hardware resource, with its various functional components embodied by executing a dedicated controlling and processing software program installed on the personal computer.

### 2. Configuration of Main Components

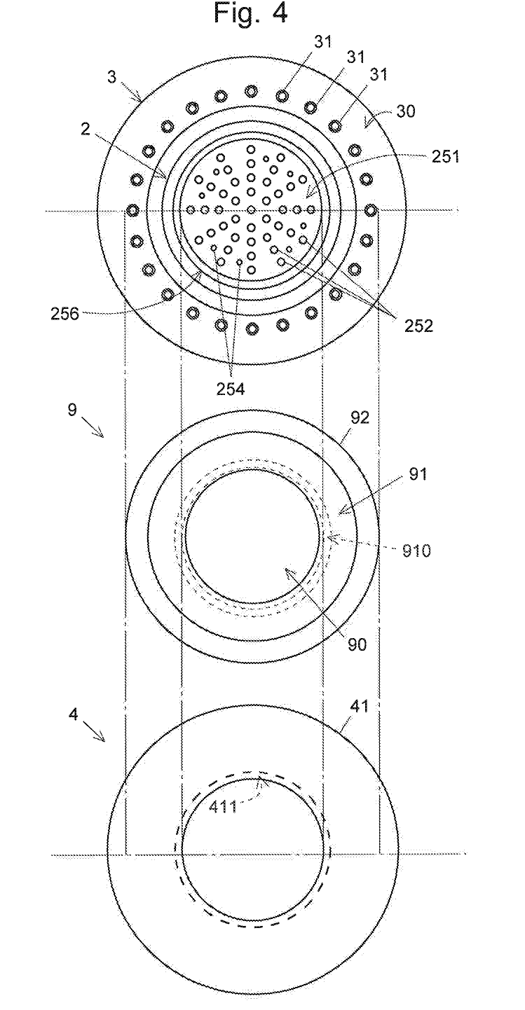

The configurations of the wafer stage 2, frame stage 3 and pressing device 4 are hereinafter described in detail with reference to FIG. 4 in addition to FIGS. 1-3. FIG. 4 is a top view of the wafer stage 2 and the frame stage 3, as well as top views of the framed wafer 9 and the pressing device 4.

<Frame Stage 3>

Frame stage 3 is the component for supporting the frame 92 of the framed wafer 9. Its top surface forms a frame placement surface 30 on which the frame 92 is to be placed. A plurality of frame-lifting pins 31 for changing the vertical position of the frame 92 relative to the frame placement surface 30 are provided in the frame stage 3. The plurality of frame-lifting pins 31 are arranged at intervals in the circumferential direction of the frame placement surface 30. A frame-lifting-pin drive mechanism 32 for changing the vertical position of the frame-lifting pin 31 between the protruded position (where the tip of the pin is protruded from the frame placement surface 30) and the retracted position (where the tip of the pin is retracted below the frame placement surface 30) is connected to each frame-lifting pin 31.

A frame-lifting-pin drive controller 33 for controlling the frame-lifting-pin drive mechanism 32 is electrically connected to the frame-lifting-pin drive mechanisms 32. Each frame-lifting-pin drive mechanism 32 vertically drives the corresponding frame-lifting pin 31 based on a command from the frame-lifting-pin drive controller 33. Specifically, the frame-lifting-pin drive controller 33 performs a drive control of the frame-lift pin drive mechanisms 32 so as to lower the individual frame-lifting pins 31 with different timings (details of this control will be described later). It should be noted that the frame-lifting-pin drive controller 33 is a functional component realized by the control unit 5 of the wafer processing device 100.

<Wafer Stage 2>

Wafer stage 2 is a component on which the wafer 90 of the framed wafer 9 is to be placed. It also functions as a lower electrode for applying a bias voltage to the wafer 90 placed on it. More specifically, the wafer stage 2 has an embedded electrode (biasing electrode) 21, to which a radio-frequency power source (biasing radio-frequency power source) 24 is connected via a blocking capacitor 22 and a matching circuit 23, thereby allowing for the application of a bias voltage to the wafer 90 placed on the wafer stage 2. A 13.56 MHz radio-frequency power source can be used as the biasing radio-frequency power source 24. In that case, the 13.56 MHz radio-frequency power may be directly supplied to the biasing electrode 21, or the 13.56 MHz radio-frequency power may be supplied to the biasing electrode 21 after being pulsed or modulated.

The wafer stage 2 is further provided with an electrostatic chuck mechanism 25 for holding the wafer 90 placed on the wafer stage 2. The electrostatic chuck mechanism 25 is constructed on the base part 250 of the wafer stage 2. The base part 250 is the part for supporting the wafer 90 of the framed wafer 9. Its upper surface has a circular shape in a planar view (circular area 251), with its outer diameter approximately equal to or slightly larger than the outer diameter of the wafer 90. The circular area 251 has a plurality of projections 252 formed by embossing. Those projections 252 come in contact with the wafer 90 (specifically, the film under the wafer) from below to support the wafer 90. The upper surface of each projection 252 is level with (at the same height as) the frame placement surface 30.

The base part 250 is made of a dielectric material. In the dielectric layer formed in this manner, an electrode (electrostatic adsorption electrode) 253 is embedded. A power source (not shown) is connected to this electrode. When direct current is supplied from the power source to the electrostatic adsorption electrode 253, an electrostatic adsorption force occurs, and the wafer 90 supported on the plurality of projections 252 is firmly held by adsorption. It should be noted that the electrostatic adsorption electrode 253 is arranged so that it will not stick out from the circular area 251 as viewed from above (i.e. so that it is entirely included inside a bank part 256, which will be described later), thereby preventing the electrostatic adsorption force from occurring in the bank part 256.

Additionally, one or more openings 254 are formed in the base part 250. A supply source of a coolant (e.g. helium) is connected to those openings via pipes 255. The coolant fed through those openings is supplied to the space above the circular area 251.

The base part 250 is circumferentially surrounded by a ring-shaped bank part 256. The bank part 256 has a flat upper surface, which is level with (at the same height as) the frame placement surface 30 and the upper surfaces of the projections 252. The upper surface of the bank part 256 comes in contact with a portion of the film 91 just outside the wafer 90 in the framed wafer 9 (this portion is hereinafter called the “wafer-adjacent film portion 910”) from below to support the same portion. The bank part 256 may preferably be made of a non-dielectric material. In the shown example, the outer diameter of a pedestal part 20 of the wafer stage 2 is larger than that of the bank part 256. These two parts may have the same outer diameter.

<Pressing Device 4>

Pressing device 4 has a pressing element 41 shaped like a ring having a large width. The outer diameter of the pressing element 41 is larger than that of the framed wafer 9 (i.e. the outer diameter of the frame 92). The inner edge portion of the pressing element 41 extends downward. The lower end surface 411 of this extending portion is shaped like a ring which coincides with the bank part 256 as viewed from above. A pressing element drive mechanism 42 for changing the vertical position of the pressing element 41 between a position sufficiently separated from the wafer stage 2 (retreated position) and a position where the lower end surface 411 comes in contact with the bank part 256 (pressing position) is connected to the pressing element 41.

A pressing element drive controller 43 for controlling the pressing element drive mechanism 42 is electrically connected to the same mechanism. The pressing element drive mechanism 42 vertically drives the pressing element 41 based on a command from the pressing element drive controller 43. It should be noted that the pressing element drive controller 43 is a functional component realized by the control unit 5 of the wafer processing device 100.

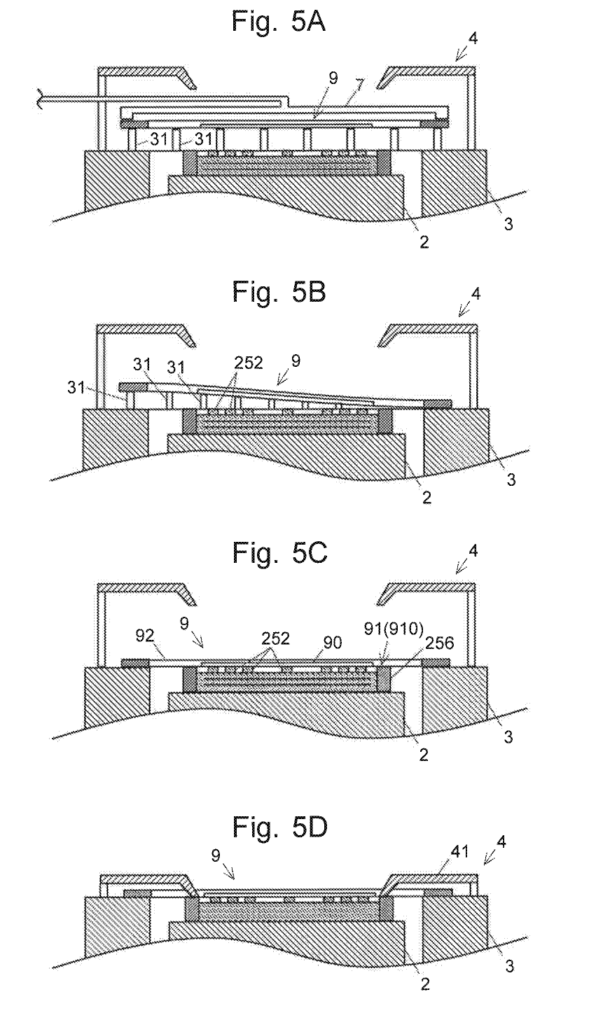

As described earlier, when the frame 92 of the framed wafer 9 is set on the frame placement surface 30 of the frame stage 3, the wafer 90 is supported on the base part 250 of the electrostatic chuck mechanism 25 (specifically, on the plurality of projections 252 formed on the base part 250), with the film 91 sandwiched in between, while the wafer-adjacent film portion 910 is supported on the bank part 256. In this state, when the pressing element 41 is lowered to the pressing position, the wafer-adjacent film portion 910 (i.e. the portion of the film located just outside the wafer 90 along the entire circumference of the wafer 90) becomes entirely pressed onto the wafer stage 2 (i.e. the wafer-adjacent film portion 910 becomes entirely sandwiched between the lower end surface 411 of the pressing element 41 and the bank part 256; see FIG. 5D). Both the bank part 256 and the lower end surface 411 have a sufficient degree of flatness. Therefore, by being sandwiched between these two components, the entire wafer-adjacent film portion 910 achieves airtight contact with the bank part 256 over the entire circumference. Meanwhile, the lower side surface 412 of the pressing element 41 is positioned close to the frame 92 and the portion of the film outside the wafer-adjacent film portion 910 in a contactless form. Thus, the frame 92 and the portion of the film 91 to which the wafer 90 is not attached are almost entirely covered by the pressing element 41.

### 3. Operation of Wafer Processing Device 100

An operation performed in the wafer processing device 100 is hereinafter described with reference to FIGS. 5A-5D in addition to FIGS. 1-4. FIGS. 5A-5D are diagrams schematically showing the state of the components 2, 3 and 4 at each stage of the sequence of operations.

Initially, an external transfer system (not shown) located outside the wafer processing device 100 (i.e. under atmospheric pressure) inserts its hand 7 into the cassette C (FIG. 2) and holds one of the framed wafers 9 stored in the cassette C with that hand 7. A specific example of the hand 7 is a device which holds the framed wafer 9 by suctioning the frame 92 of the framed wafer 9 from above. An appropriate suction system may be adopted for the hand 7, such as a vacuum suction system or Bernoulli system.

Subsequently, the load lock 12 of the wafer processing device 100 is opened, and the hand 7 of the external transfer system holding the framed wafer 9 is inserted from the transfer opening 11. In this phase, the group of frame-lifting pins 31 in the frame stage 3 are all set at the projected position. The hand 7 holding the framed wafer 9 sets its frame 92 onto those frame-lifting pins 31 (FIG. 5A) and releases the frame 92 from the suctioned state. In this manner, the framed wafer 9 is transferred from the hand 7 onto the group of frame-lifting pins 31. Subsequently, the hand 7 is withdrawn through the transfer opening 11 to the outside, and the load lock 12 is closed.

Subsequently, each frame-lifting pin 31 is lowered from the projected position to the retracted position. It should be noted that the frame-lifting-pin drive controller 33 performs a drive control of the frame-lift pin drive mechanisms 32 so as to lower the individual frame-lifting pins 31 with different timings. That is to say, the timing to lower each of the frame-lifting pins 31 is controlled so that a portion of the film 91 initially comes in contact with only a portion of the wafer stage 2 (specifically, a portion of the group of projections 252 formed within the circular area 251), and subsequently, the contact area gradually extends from the initial contact portion to other portions (specifically, the number of projections 252 which come in contact with the film 91 gradually increases), until the entire wafer stage 2 (specifically, the entire group of the projections 252 formed within the circular area 251) comes in contact with the film 91 (FIG. 5B).

For example, the previously described mode of driving may specifically be performed as follows:

Initially, a first frame-lifting pin 31 is made to begin descending. At a slightly later point in time, the adjacent frame-lift pins 31 on both sides of the first pin are made to begin descending. At a further later point in time, two more adjacent frame-lift pins 31 (on the sides on which the descending operation has not yet been initiated) are made to begin descending. In this manner, the individual frame-lifting pins 31 are successively made to descend with different timings.

When the last frame-lifting pin 31 has been lowered to the retracted position, the frame 92 is entirely set on the frame placement surface 30 (FIG. 5C). In this state, both the film 91 and the wafer 90 attached on the same film lie on the wafer stage 2. That is to say, the wafer 90 is supported on the circular area 251 of the electrostatic chuck mechanism 25 (specifically, on the plurality of projections 252 formed within the same area), with the film 91 sandwiched in between, while the wafer-adjacent film portion 910 is supported on the bank part 256. Since the frame-lifting pins 31 are not simultaneously lowered but are individually lowered with different timings by the frame-lifting-pin drive controller 33, both the film 91 and the wafer 90 attached on the same film are neatly set on the wafer stage 2 (i.e. with no wrinkle in the film 91 as well as no bubble between the film 91 and the bank part 256).

Subsequently, direct current is supplied to the electrostatic adsorption electrode 253. As a result, the wafer 90 supported on the projections 252 is firmly held by the electrostatic adsorption force. The supply of the direct current to the electrostatic adsorption electrode 253 may be initiated before the wafer 90 is completely set on the wafer stage 2 (e.g. simultaneously with the beginning of the lowering of the first frame-lifting pin 31).

Subsequently, the pressing element drive controller 43 performs a drive control of the pressing element drive mechanism 42 to lower the pressing element 41 from the retreated position to the pressing position (FIG. 5D). As a result, the wafer-adjacent film portion 910 is sandwiched between the lower end surface 411 of the pressing element 41 and the bank part 256, whereby a secure fixation of the wafer 90 to the wafer stage 2 is achieved.

Subsequently, the supply of the coolant to the opening 254 formed in the base part 250 is initiated. Since the wafer 90 placed on the wafer stage 2 is supported by the projections 252 within the circular area 251 surrounded by the bank part 256, the coolant passes through the space surrounded by the wafer 90 and the bank part 256, whereby the wafer 90 is cooled. In particular, since the entire wafer-adjacent film portion 910 is made to be in airtight contact with the entire circumference of the bank part 256 by the pressing element 41, the coolant supplied to the aforementioned space cannot escape to the outside (i.e. the coolant is prevented from leaking through a gap between the film 91 and the wafer stage 2), so that the wafer 90 can be efficiently cooled.

Subsequently, the evacuation of the gas from the processing space V is initiated. When the processing space V has reached a sufficiently high degree of vacuum, the supply of a predetermined kind of gas to the processing space V is initiated. Additionally, the radio-frequency power for plasma formation is supplied from the radio-frequency power source for plasma 16 to the radio-frequency coil 14. A biasing radio-frequency power is also supplied from the biasing radio-frequency power source 24 to the biasing electrode 21 in the wafer stage 2. As a result, a cloud of plasma is formed above the wafer 90, causing the surface of this wafer 90 to be progressively etched with the thereby generated reactive ions in the plasma. It should be noted that a mask which covers the areas other than the streets is previously formed on the surface of the wafer 90. Accordingly, only the street portions which are not covered with the mask undergo the etching. In other words, the plasma dicing processing progresses. The mask which covers the areas other than the streets can be formed by initially forming a mask which covers the entire wafer 90 and subsequently removing the portions of the mask covering the streets with a laser (JP 2005-191039 A) or rotary blade (JP 2001-127011 A). Such a mask pattern should be created at an appropriate timing before the transfer of the framed wafer 9 into the plasma processing device 100.

It should be noted that the pressing element 41 is already lowered to the pressing position in advance of the formation of the plasma in the processing space V. The frame 92 as well as the portion of the film 91 to which the wafer 90 is not attached are almost entirely covered by the pressing element 41. Accordingly, the situation where the film 91 is damaged due to exposure to the plasma is prevented during the plasma dicing processing. The generation of particles from the frame 92 and the film 91 due to their exposure to the plasma is also prevented.

If the wafer 90 is a silicon wafer, the plasma dicing processing may preferably be performed by a Bosch process. In the Bosch process, the steps of performing isotropic etching (etching step), depositing a protective layer (protective layer formation step), and removing the protective layer from the bottom surface (bottom surface removal step) are cyclically repeated. By this process, silicon can be progressively excavated in the vertical direction with high aspect ratios (i.e. a dicing processing with high aspect ratios can be performed). In this case, SF₆ is preferable as the gas to be used in the etching step. C₄F₈ is preferable as the gas to be used in the protective layer formation step. As for the bottom surface removal step, it is preferable to use at least one kind of gas selected from CF₄, NF₃, F₂ and COF₂.

With the increase in the depth of the trench being excavated by the etching, the intensity of light changes which results from the reaction between the plasma and the particles generated by etching. Additionally, when the bottom of the trench reaches the film 91 (i.e. when the trench penetrates through the wafer 90), the kind of particles present in the processing space V changes, which causes a change in the peak position of the spectrum of the light. Accordingly, it is preferable to provide the wafer processing device 100 with an emission analyzer for measuring the emission spectrum in the processing space V and determine the timing to discontinue the plasma dicing processing based on the emission spectrum measured with the analyzer.

In the case of performing the plasma dicing processing by the Bosch process, an undulating structure called the “scallops” may remain on the sidewall of the fabricated trench (i.e. on the side surfaces of the individual unit circuits obtained by the dividing and cutting process). Accordingly, it is also preferable to perform a process for removing the scallops after the completion of the plasma dicing process. For example, the process may specifically be performed by carrying out the plasma processing with F₂ introduced into the processing space V. Another possible example is to introduce at least one kind of gas selected from O₂, N₂O, NO, CO and H₂ into the processing space V, and continue the reactive ion etching process with a negative bias voltage applied to the wafer 90.

After the completion of the predetermined processings, the gas supply is discontinued, and the power supplies to the radio-frequency coil 14 and the biasing electrode 21 are also discontinued. Then, the framed wafer 9 is removed from the wafer processing device 100.

The operation of removing the framed wafer 9 from the wafer processing device 100 is basically performed by reversing the order of the steps of transferring the framed wafer 9 into the wafer processing device 100 (FIGS. 5A-5D).

Initially, the pressing element 41 is lifted from the pressing position to the retreated position. In this process, the wafer-adjacent film portion 910 may possibly be adhered to the lower end surface 411 of the pressing element 41, causing the framed wafer 9 to be pulled upward. In order to prevent such a situation, when the pressing element 41 is to be lifted, it is preferable to discontinue the supply of the coolant to the circular area 251, as well as perform a suctioning operation through the openings 254 to create negative pressure within the space surrounded by the base part 250, film 91 and bank part 256. Furthermore, it is preferable to hold the wafer 90 in the adsorbed state by maintaining the supply of the direct current to the electrostatic adsorption electrode 253 at least until the pressing element 41 is completely separated from the framed wafer 9.

Subsequently, the supply of the direct current to the electrostatic adsorption electrode 253 is discontinued. As a result, the wafer 90 is released from the adsorbed state. In this process, a plasma for removing static electricity may be generated within the processing space V to completely remove the electrostatic adsorption force acting on the wafer 90.

Subsequently, the group of frame-lifting pins 31 is driven upward from the retracted position to the protruded position. This time, it is unnecessary to drive the individual frame-lifting pins 31 with different timings; the group of frame-lifting pins 31 may be simultaneously driven upward. As noted earlier, the electrostatic adsorption force is not acting on the bank part 256. Therefore, the wafer-adjacent film portion 910 which has been pressed onto the bank part 256 can be easily separated from the bank part 256 with the upward movement of the frame-lifting pins 31. It is also preferable to eject a nitrogen gas or the like from the openings 254 to increase the pressure within the space between the circular area 251 and the film 91 in advance of the beginning of the upward driving of the frame-lifting pins 31.

After the group of frame-lifting pins 31 has been set at the protruded position, the load lock 12 is opened, and the hand 7 of the external transfer system is inserted through the transfer opening 11 to hold the framed wafer 9 by suctioning the frame 92 of the framed wafer 9 supported on the group of frame-lifting pins 31. Subsequently, the hand 7 is withdrawn from the transfer opening 11 and stores the thereby held framed wafer 9 into the cassette C.

### 4. Variations

### First Variation

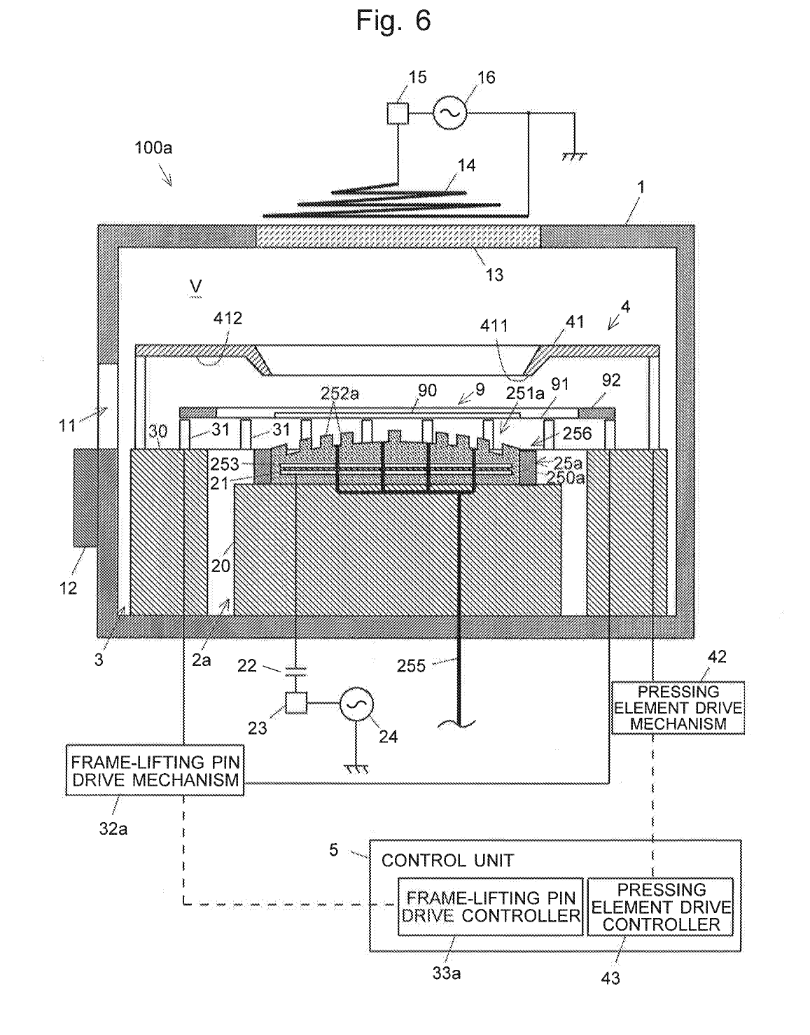

In the previous embodiment, the wafer stage 2 may be modified to support the wafer 90 in a curved form via the film 91. That is to say, as shown in FIG. 6, the upper surface of the wafer stage 2a may have a curved surface bulging upward. Specifically, the base part 250 of the electrostatic chuck mechanism 25a may have a curved upper surface with a specific shape (a curved surface whose radius of curvature is sufficiently larger than the radius of the wafer 90). According to this configuration, it is unnecessary to lower the individual frame-lifting pins 31 with different timings. The frame-lifting-pin drive controller 33a controls the frame-lifting-pin drive mechanism 32a to simultaneously lower the group of frame-lifting pins 31.

In this wafer processing device 100a, the wafer 90 is placed onto the wafer stage 2a as follows: After the frame 92 of the framed wafer 9 has been in the state of being supported by the plurality of frame-lifting pins 31 (see FIG. 5A), the frame-lifting-pin drive controller 33a controls the frame-lifting-pin drive mechanism 32a to simultaneously lower the group of frame-lifting pins 31. Since the upper surface of the wafer stage 2a is a curved surface bulging upward, only a central portion of the lower surface of the film 91 with the attached wafer 90 initially comes in contact with the wafer stage 2a (specifically, with the projections 252a formed within a central portion of the circular area 251a), rather than the entire surface of the film 91 simultaneously coming in contact with the wafer stage 2a. Subsequently, the contact area gradually extends from the initial contact portion to the surrounding portions, until the entire lower surface of the film 91 comes in contact with the stage (i.e. all projections 252a formed within the circular area 251a come in contact with the film 91). As a result, both the film 91 and the wafer 90 attached to the film are neatly placed on the wafer stage 2a.

In this wafer processing device 100a, it is preferable to form the electrostatic adsorption electrode 253 by concentrically arranging a plurality of ring-shaped electrodes having different diameters and synchronize the timing of initiating the supply of the direct current to each ring-shaped electrode with the timing of the contact of the film 91. In other words, it is preferable to shift the timing of initiating the supply of the direct current in a stepwise manner from inner to outer electrodes in accordance with the timing of the contact of the film 91.

### Second Variation

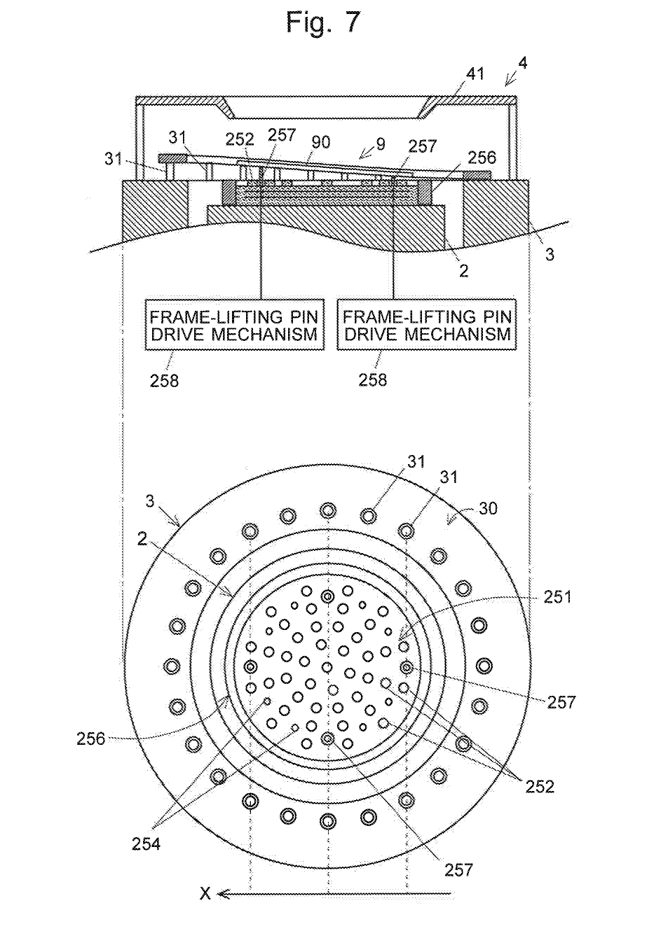

In the previous embodiment, a plurality of wafer-lifting pins 257 may be provided at intervals within the circular area 251 of the electrostatic chuck mechanism 25, and a wafer-lifting-pin vertical drive mechanism 258 for changing the vertical position of the wafer-lifting pin 257 between the projected position (where the tip of the pin is higher than the upper surface of the projections 252) and the retracted position (where the tip of the pin is lower than the upper surface of the projections 252) may be connected to each of those wafer-lifting pins 257 (FIG. 7). The wafer-lifting-pin vertical drive mechanisms 258 lower the individual wafer-lifting pins 257 with different timings. That is to say, the wafer-lifting-pin vertical drive mechanisms 258 control the position of each wafer-lifting pin 257 so that the wafer-lifting pins 257 support the wafer 90 of the framed wafer 9 from the bottom side via the film 91 to prevent the wafer 90 from sagging while being lowered. Specifically, for example, provided that the direction of the line which connects the first frame-lifting pin 31 to begin descending and the last frame-lifting pin 31 to begin descending is defined as the X direction, each wafer-lifting pin 257 is lowered at the same timing and the same speed as the frame-lifting pin 31 located at the same X position. By such a control, the wafer 90 of the framed wafer 9 supported by the frame-lifting pins 31 is prevented from sagging due to its weight while those pins are being lowered from the projected position to the retracted position.

### Third Variation

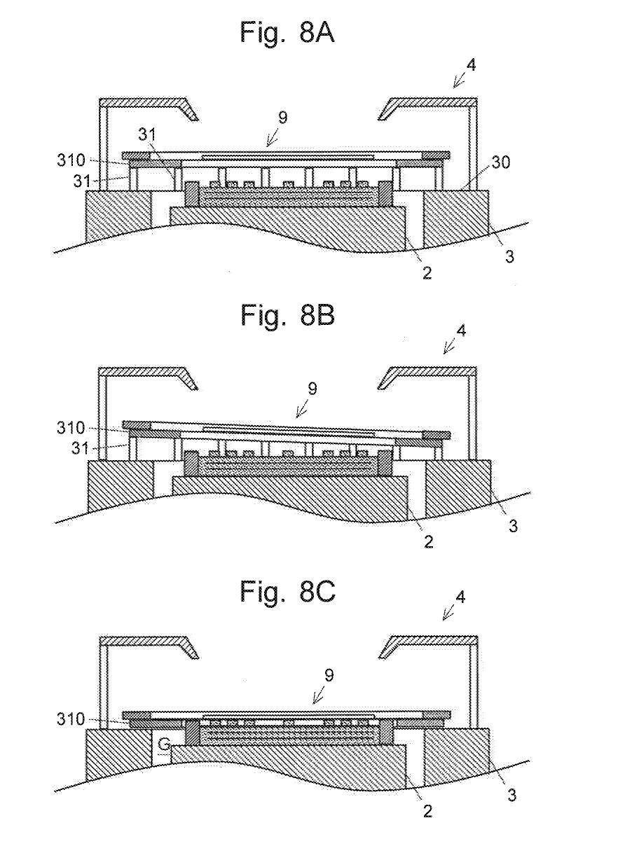

In the previous embodiment, a frame placement plate 310 consisting of a ring-shaped thin plate may be fixed to the upper side of the group of frame-lifting pins 31 (FIG. 8). In this case, the inner diameter of the frame placement plate 310 may preferably be almost equal to or slightly larger than the outer diameter of the bank part 256, while its outer diameter may preferably be sufficiently larger than the inner diameter of the frame 92. In the case of providing the frame placement plate 310, the upper surface of the frame stage 3 should be at a level which is lower than the upper surface of the bank part 256 by the thickness of the frame placement plate 310.

In this variation, when the group of frame-lifting pins 31 is at the projected position, the frame 92 of the framed wafer 9 is supported by those frame-lifting pins 31 via the frame placement plate 310 (FIG. 8A). When the frame-lifting pins 31 are individually lowered with different timings, the frame placement plate 310 fixed to those pins moves downward in an inclined position, and the thereby supported frame 92 also moves downward in an inclined position (FIG. 8B). When all frame-lifting pins 31 have reached the retracted position (i.e. when the framed wafer 9 has been placed on the wafer stage 2), the frame 92 is set on the frame stage 3, with the frame placement plate 310 sandwiched in between (FIG. 8C). In this state, the upper surface of the frame placement plate 310 is located close to the portion outside the wafer-adjacent film portion 910 on the lower surface of the film 91 of the framed wafer 9. Therefore, the situation where the lower surface of the film 91 is damaged due to exposure to plasma (which is present in the space (gap) G between the outer sidewall of the wafer stage 2 and the inner sidewall of the frame stage 3) can be avoided.

### Fourth Variation

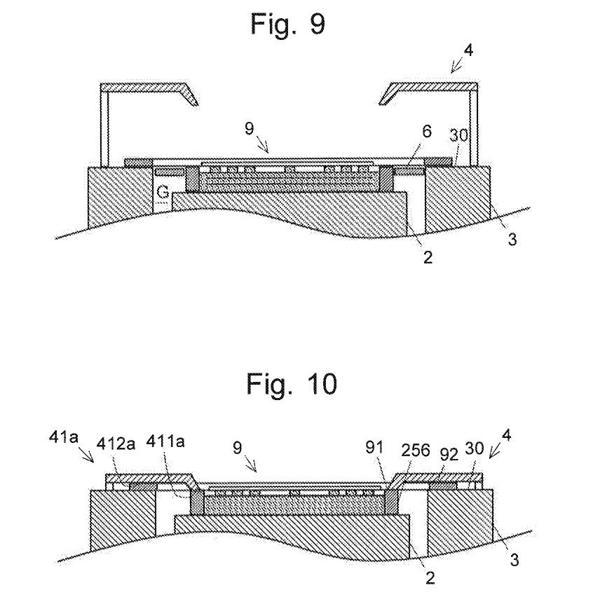

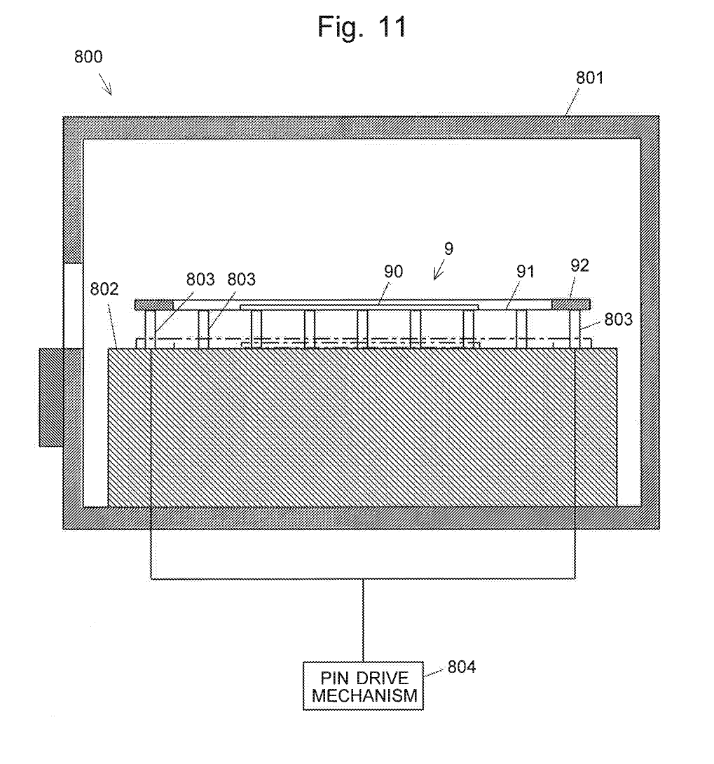

In the previous embodiment, a ring-shaped thin plate 6 having substantially the same shape as the space (gap) G between the outer sidewall of the wafer stage 2 and the inner sidewall of the frame stage 3 in a plan view may be provided in a fixed (or removable) form at a position where the upper surface of the thin plate 6 is located at the same level as (or slightly lower than) the frame placement surface 30 (FIG. 9). This thin plate 6 should be used to close the gap G at least during the plasma dicing process. When the framed wafer 9 is set on the wafer stage 2, the upper surface of this thin plate 6 is in contact with (or not in contact with but close to) the portion outside the wafer-adjacent film portion 910 on the lower surface of the film 91. Therefore, the situation where the lower surface of the film 91 is damaged due to exposure to plasma (which is present in the gap G) can be avoided.

### Fifth Variation

In the previous embodiment, the pressing element 41 is configured to press the wafer-adjacent film portion 910 onto the bank part 256. This element may be modified to press the frame 92 onto the frame placement surface 30 in addition to the wafer-adjacent film portion 910 (FIG. 10). Specifically, the downward-extending portion of the pressing element 41a may be configured to have the same thickness as the frame 92. This pressing element 41a can press both the wafer-adjacent film portion 910 onto the bank part 256 with its lower end surface 411a and the frame 92 onto the frame placement surface 30 with its lower side surface 412a when the pressing element 41a is at the pressing position.

With this pressing element 41a, it is possible to press both the wafer-adjacent film portion 910 and the frame 92, so that a securer fixation of the wafer 90 to the wafer stage 2 is achieved. The pressing element 41 according to the previous embodiment does not come in contact with the frame 92 and therefore cannot apply so much fixing power to the wafer 90 as the pressing element 41a according to the present variation. However, it has the advantage that the flatness and positional accuracy of the lower side surface 412 (i.e. the positional accuracy of the lower side surface 412 relative to the lower end surface 411) is allowed to be low, as long as that the flatness and positional accuracy of the lower end surface 411 is sufficiently high.

### Sixth Variation

In the wafer processing device 100 according to the previous embodiment, the load lock 12 may be replaced by a load lock chamber, with the external transfer system placed inside to perform the transfer of the framed wafer 9 into and from the wafer processing device 100. In this case, it is unnecessary to provide the hand 7 of the external transfer system with the mechanism for suctioning the frame 92. For example, a hand which comes in contact with the lower surface of the frame 92 to support the frame may be used.

### Seventh Variation

In the previous embodiment, a 13.56 MHz radio-frequency power source is used as the biasing radio-frequency power source 24. The power supplied to the biasing electrode 21 does not always need to be radio-frequency power. For example, it is possible to replace the biasing radio-frequency power source 24 by a power source with a low frequency of around 400 Hz and supply the biasing power from this power source to the biasing electrode 21. In this case, the low-frequency power of around 400 Hz may be directly supplied, or the power may be supplied after being pulsed or modulated. The use of the low-frequency power of around 400 Hz as the biasing power prevents the progress of the etching in the lateral direction (the so-called “notching”) at the interface between the wafer 90 and the film 91.

### Eighth Variation

In the previous embodiment, it is possible to perform a predetermined pretreatment on the wafer 90 when the framed wafer 9 is supported on the group of frame-lifting pins 31 at the projected position (or when the entire group of frame-lifting pins 31 is temporarily halted in the middle of their descending motion, or while the frame-lifting pins 31 are descending). The “pretreatment” is a treatment for increasing the adsorption force of the wafer 90 and the film 91 to the electrostatic chuck mechanism 25. For example, this may specifically be achieved by treating the wafer 90 for a predetermined period of time using the same kind of plasma as the one used for the intended processing (in the present case, the plasma dicing processing). A different kind of plasma or a weaker plasma may also be used for this pretreatment.

### REFERENCE SIGNS LIST

100, 100a . . . Wafer Processing Device
1 . . . Housing
   11 . . . Transfer Opening
   12 . . . Load Lock
   13 . . . Dielectric Window
   14 . . . Radio-Frequency Coil
   15 . . . Matching Circuit
   16 . . . Radio-Frequency Power Source for Plasma
2, 2a . . . Stage (Wafer Stage)
   20 . . . Pedestal Part
   21 . . . Biasing Electrode
   22 . . . Blocking Capacitor
   23 . . . Matching Circuit
   24 . . . Biasing Radio-Frequency Power Source
   25, 25a . . . Electrostatic Chuck Mechanism
      250 . . . Base Part
      251, 251a . . . Circular Area
      252 . . . Projection
      253 . . . Electrostatic Adsorption Electrode
      254 . . . Opening
      255 . . . Pipe
      256 . . . Bank Part
      257 . . . Wafer-Lifting Pin
      258 . . . Wafer-Lifting-Pin Vertical Drive Mechanism
3 . . . Frame Stage
   30 . . . Frame Placement Surface 31 . . . Frame-Lifting Pin
   310 . . . Frame Placement Plate
   32 . . . Frame-Lifting-Pin Drive Mechanism
   32, 32a . . . Frame-Lifting-Pin Drive Mechanism
   33, 33a . . . Frame-Lifting-Pin Drive Controller
4 . . . Pressing Device
   41, 41a . . . Pressing Element
      411, 411a . . . Lower End Surface
      412, 412a . . . Lower Side Surface
   42 . . . Pressing Element Drive Mechanism
   43 . . . Pressing Element Drive Controller
5 . . . Control Unit
6 . . . Thin Plate
7 . . . Hand
9 . . . Framed Wafer
   90 . . . Wafer
   91 . . . Film
      910 . . . Wafer-Adjacent Film Portion
   92 . . . Frame

1. A wafer processing device used for plasma-processing a wafer with a workpiece unit including a frame, a film stretched inside the frame, and the wafer attached on the film, the wafer processing device comprising:
a) a stage on which the wafer is to be placed via the film;
b) a plurality of vertically movable frame-lifting pins arranged around the stage, for supporting the frame; and
c) a frame-lifting-pin drive controller for lowering the plurality of vertically movable frame-lifting pins individually with different timings.

2. The wafer processing device according to claim 1, further comprising:
d) a pressing element for pressing a part of the film outside the wafer onto the stage.

3. The wafer processing device according to claim 2, wherein:
the pressing element is configured to press the film located just outside the wafer along an entire circumference of the wafer.

4. The wafer processing device according to claim 2, wherein:
the pressing element is configured to cover, in a contactless form, the frame as well as a part of the film outside a position of the film pressed by the pressing element.

5. The wafer processing device according to claim 1, wherein the stage comprises:
a frame-shaped bank part for supporting the film just outside the wafer;
a base part surrounded by the frame-shaped bank part; and
a plurality of projections provided on the base part, each of the plurality of projections having an upper end at a same height as an upper surface of the bank part.

6. The wafer processing device according to claim 5, wherein:
the stage comprises an electrostatic chuck mechanism which comprises:
a dielectric layer serving as the base part; and
an electrode located within an inner area than the bank part as viewed from above and at a lower level than an upper surface of the dielectric layer.

7. The wafer processing device according to claim 1, further comprising:
a frame stage circumferentially surrounding the aforementioned stage, leaving a space from the aforementioned stage,
wherein the plurality of frame-lifting pins are provided in the frame stage.

8. A wafer processing device used for plasma-processing a wafer with a workpiece unit including a frame, a film stretched inside the frame, and the wafer attached on the film, the wafer processing device comprising:
a) a stage on which the wafer is to be placed via the film, the stage having a top surface including a curved surface bulging upward; and
b) a plurality of vertically movable frame-lifting pins arranged around the stage, for supporting the frame.
